(19) United States
(12) Patent Application Publication
(10) Pub. No.: US 2015/0004752 A1
(43) Pub. Date: Jan. 1, 2015

(54) SEMICONDUCTOR PACKAGE, SEMICONDUCTOR SUBSTRATE, SEMICONDUCTOR STRUCTURE AND FABRICATION METHOD THEREOF

(71) Applicant: Siliconware Precision Industries Co., Ltd., Taichung (TW)

(72) Inventors: Chang-Fu Lin, Taichung (TW); Chin-Tsai Yao, Taichung (TW); Ming-Chin Chuang, Taichung (TW); Keng-Hung Liu, Taichung (TW); Fu-Tang Huang, Taichung (TW)

(73) Assignee: Siliconware Precision Industries Co., Ltd., Taichung (TW)

(21) Appl. No.: 14/085,959

(22) Filed: Nov. 21, 2013

(30) Foreign Application Priority Data
Jul. 1, 2013 (TW) 102123429

(51) Int. Cl. H01L 21/78; H01L 23/544

(52) U.S. Cl. CPC H01L 21/78; H01L 23/544
USPC 438/113; 257/620; 438/460; 438/463

(57) ABSTRACT

A semiconductor package is disclosed, which includes: a packaging substrate; a semiconductor element disposed on the packaging substrate in a flip-chip manner; a stopping portion formed at edges of the semiconductor element; an insulating layer formed on an active surface of the semiconductor element and the stopping portion; and an encapsulant formed between the packaging substrate and the insulating layer. The insulating layer has a recessed portion formed on the stopping portion and facing the packaging substrate such that during a reliability test, the recessed portion can prevent delamination occurring between the insulating layer and the stopping portion from extending to the active surface of the semiconductor element.

### BACKGROUND OF THE INVENTION

1. Field of the Invention

The present invention relates to semiconductor packages, semiconductor substrates, semiconductor structures and fabrication methods thereof, and more particularly, to a flip-chip semiconductor package, a semiconductor substrate, a semiconductor structure and a fabrication method thereof.

2. Description of Related Art

Along with the rapid development of electronic industries, electronic products have been reduced in size and developed towards high performance, high functionality and high speed. To meet the high integration and miniaturization requirements of semiconductor devices, flip-chip packaging technologies have been developed to increase the wiring density. To fabricate semiconductor chips for flip-chip processing, a semiconductor wafer comprised of a plurality of semiconductor chips is cut along cutting paths to singulate the semiconductor chips. Before the cutting process, a passivation layer made of such as polyimide is generally formed on the wafer. Since the passivation layer increases the cutting difficulty and easily causes damages to a cutting tool, the passivation layer is not formed on the cutting paths.

FIG. 1A is a schematic cross-sectional view of a conventional flip-chip semiconductor package 1. Referring to FIG. 1A, the semiconductor package 1 has a packaging substrate 14, a semiconductor element 10 disposed on the packaging substrate 14, an insulating layer 12 formed on the semiconductor element 10, and an encapsulant 15 formed between the packaging substrate 14 and the insulating layer 12. The semiconductor element 10 has an active surface 10a and a non-active surface 10b opposite to the active surface 10a. The active surface 10a of the semiconductor element 10 has a plurality of electrode pads 100 and a seal ring 101 (shown in FIG. 1B) along edges of the active surface 10a of the semiconductor element 10. The insulating layer 12 is formed on the active surface 10a of the semiconductor element 10 and the electrode pads 100 are exposed from the insulating layer 12. The semiconductor element 10 is disposed on the packaging substrate 14 with the active surface 10a facing the packaging substrate 14 and the electrode pads 100 of the active surface 10a being electrically connected to the packaging substrate 14 through a plurality of conductive elements 16. Further, side surfaces of the semiconductor element 10 and the insulating layer 12 are covered by the encapsulant 15.

However, under a reliability test of the semiconductor element 10, since there are great stresses on four corners of the semiconductor element 10, delamination easily occurs between the encapsulant 15 and the semiconductor element 10. As such, delamination easily occurs between the insulating layer 12 and the semiconductor element 10 and extends to the electrode pads 100 of the active surface 10a of the semiconductor element 10, as shown in dashed lines of FIG. 1B, thereby reducing the product yield.

Therefore, how to overcome the above-described drawbacks has become urgent.

### SUMMARY OF THE INVENTION

In view of the above-described drawbacks, the present invention provides a fabrication method of a semiconductor substrate, which comprises the steps of: providing a substrate body having a plurality of semiconductor elements and a plurality of cutting portions, wherein each of the semiconductor elements has opposite active and non-active surfaces, and the cutting portions are defined around peripheries of the semiconductor elements; and forming an insulating layer on the substrate body for covering the semiconductor elements and the cutting portions; and forming a plurality of recessed portions in the insulating layer.

The present invention further provides a semiconductor substrate, which comprises: a substrate body having a plurality of semiconductor elements and a plurality of cutting portions, wherein each of the semiconductor elements has opposite active and non-active surfaces, and the cutting portions are defined around peripheries of the semiconductor elements; and an insulating layer formed on the substrate body for covering the semiconductor elements and the cutting portions, wherein the insulating layer has a plurality of recessed portions.

In the above-described substrate and fabrication method thereof, a plurality of cutting grooves can further be formed in the insulating layer corresponding to the cutting portions, respectively, and the cutting grooves can have a width greater than that of the recessed portions. Each of the cuffing portions can have two of the recessed portions formed thereon and the cutting groove corresponding to the cutting portion can be formed between the two recessed portions.

In the above-described substrate and fabrication method thereof, the recessed potions can be formed on the active surfaces of the semiconductor elements and each of the cutting grooves can be formed between the recessed portions of two adjacent ones of the semiconductor elements.

In the above-described substrate and fabrication method thereof, the recessed portions can he formed on the cuffing portions. The cutting portions can be partially exposed from the recessed portions or the recessed portions can extend into the cutting portions.

The present invention further provides a fabrication method of a semiconductor package, which comprises the steps of providing a semiconductor structure, wherein the semiconductor structure comprises a semiconductor element having an active surface with a plurality of electrode pads and a non-active surface opposite to the active surface, a stopping portion formed at edges of the semiconductor element and an insulating layer firmed on the active surface of the semiconductor element and the stopping portion and exposing the electrode pads of the semiconductor element, the insulating layer having at least a recessed portion; disposing the semiconductor structure on a packaging substrate via the active surface thereof; and forming an encapsulant between the packaging substrate and the insulating layer.

In the above-described fabrication method of a semiconductor package, forming the semiconductor structure can comprise the steps of: providing a substrate body having a plurality of semiconductor elements and a plurality of cutting portions, wherein the cutting portions are defined around peripheries of the semiconductor elements; forming an insulating layer on the substrate body for covering the semiconductor elements and the cutting portions; forming a plurality of recessed portions in the insulating layer; cutting along the cutting portions to singulate the semiconductor elements, wherein portions of the cutting portions remain at edges of the semiconductor elements and serve as stopping portions of the semiconductor elements.

In the above-described fabrication method of a semiconductor package, the recessed portion can be formed by laser or exposure and development.

The present invention further provides a semiconductor package, which comprises: a packaging substrate; a semiconductor element having an active surface with a plurality of electrode pads and a non-active surface opposite to the active surface, wherein the semiconductor element is disposed on the packaging substrate via the active surface thereof; a stopping portion formed at edges of the semiconductor element; an insulating layer formed on the active surface of the semiconductor element and the stopping portion and exposing the electrode pads of the semiconductor element, wherein the insulating layer has at least a recessed portion; and an encapsulant formed between the packaging substrate and the insulating layer.

The present invention further provides a semiconductor structure, which comprises: a semiconductor element having an active surface with a plurality of electrode pads and a non-active surface opposite to the active surface; a stopping portion formed at edges of the semiconductor element; and an insulating layer formed on the active surface of the semiconductor element and the stopping portion and exposing the electrode pads of the semiconductor element, wherein the insulating layer has at least a recessed portion.

In the above-describe semiconductor package and fabrication method thereof the recessed portion can face the packaging substrate.

In the above-describe semiconductor package and fabrication method thereof the electrode pads of the semiconductor element can be electrically connected to the packaging substrate through a plurality of conductive elements.

In the above-describe semiconductor package and fabrication method thereof and the semiconductor structure, the stopping portion can be made of a semiconductor material. The stopping portion and the semiconductor element can be integrally formed.

In the above-describe semiconductor packaging and fabrication method thereof and the semiconductor structure, the recessed portion can be formed on the active surface of the semiconductor element. Further, the active surface of the semiconductor element can be partially exposed from the recessed portion.

In the above-describe semiconductor package and fabrication method thereof and the semiconductor structure, the recessed portion can be formed on the stopping portion. Further, the stopping portion can be partially exposed from the recessed portion or the recessed portion can extend into the stopping portion.

Further, the recessed portion can have a linear shape or a ring shape.

Therefore, the recessed portion of the present invention separates the portion of the insulating layer on the stopping portion from the portion of the insulating layer on the semiconductor element such that during a reliability test, delamination occurring between the insulating layer and the stopping portion can be prevented from extending to the active surface of the semiconductor element, thereby increasing the product yield.

### BRIEF DESCRIPTION OF DRAWINGS

FIG. 1A is a schematic cross-sectional view of a conventional semiconductor package;

FIG. 1B is a partially enlarged view of FIG. 1A;

FIGS. 2A to 2E″ are schematic views showing a fabrication method of a semiconductor package according to the present invention, wherein FIG. 23′ shows another embodiment of FIG. 2B, FIG. 2B″ shows a bottom view of a semiconductor substrate of the present invention, FIG. 2E shows a partially enlarged view of FIG. 2D, FIGS. 2E′ and 2E″ show other embodiments of FIG. 2E; and

FIGS. 3A and 3B are schematic views showing other embodiments of FIG. 2B″.

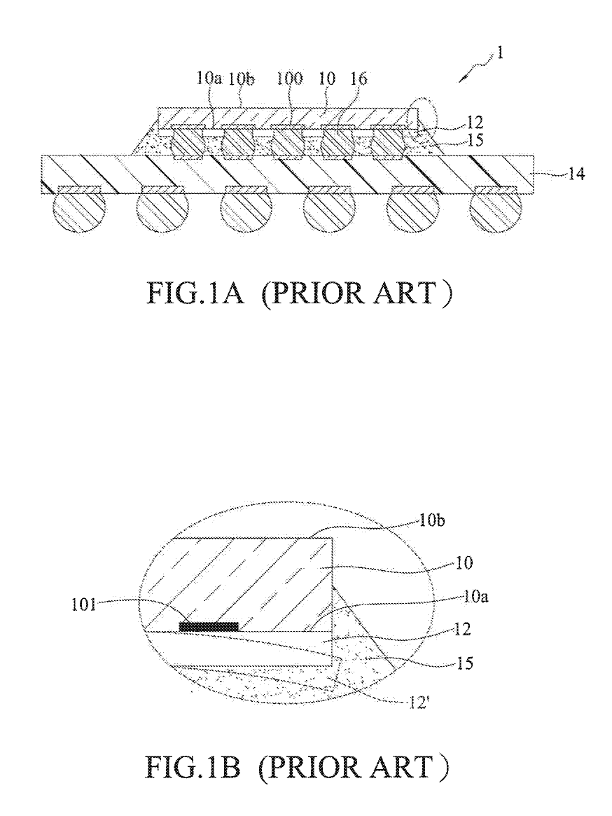

### DETAILED DESCRIPTION OF PREFERRED EMBODIMENTS

The following illustrative embodiments are provided to illustrate the disclosure of the present invention, these and other advantages and effects can be apparent to those in the art after reading this specification.

It should be noted that all the drawings are not intended to limit the present invention. Various modifications and variations can be made without departing from the spirit of the present invention. Further, terms such as “first”, “second”, “bottom”, “a” etc. are merely for illustrative purposes and should not be construed to limit the scope of the present invention.

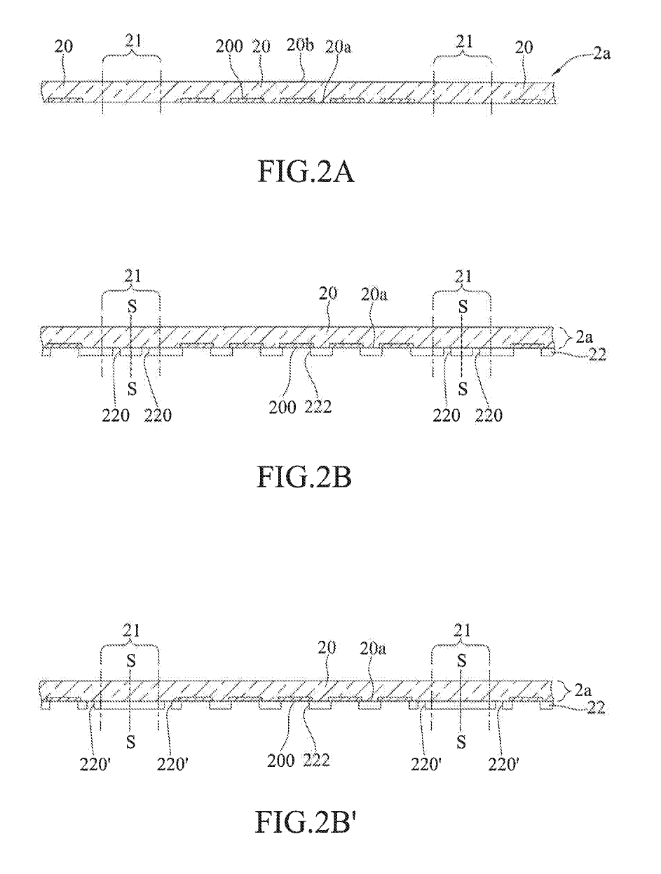

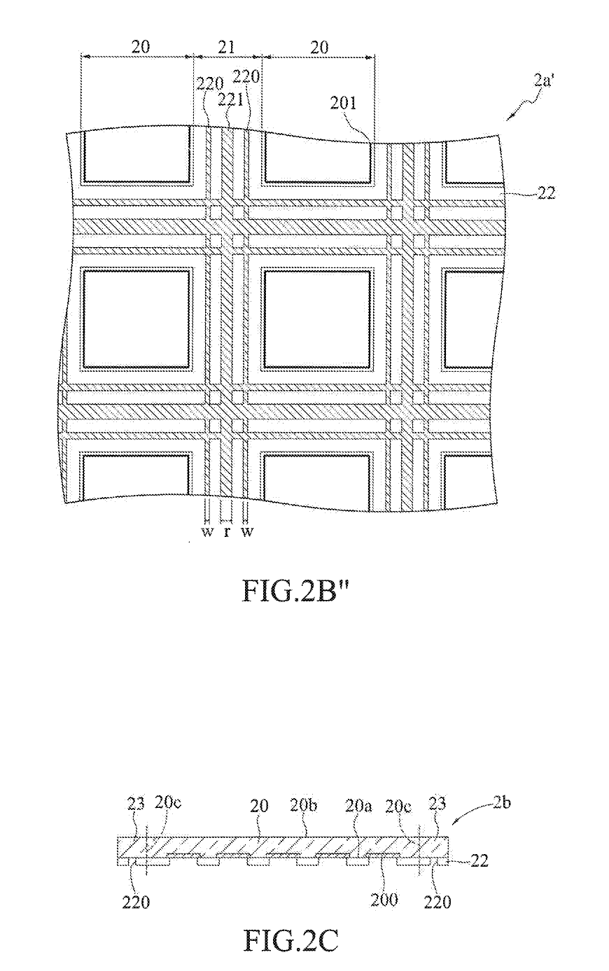

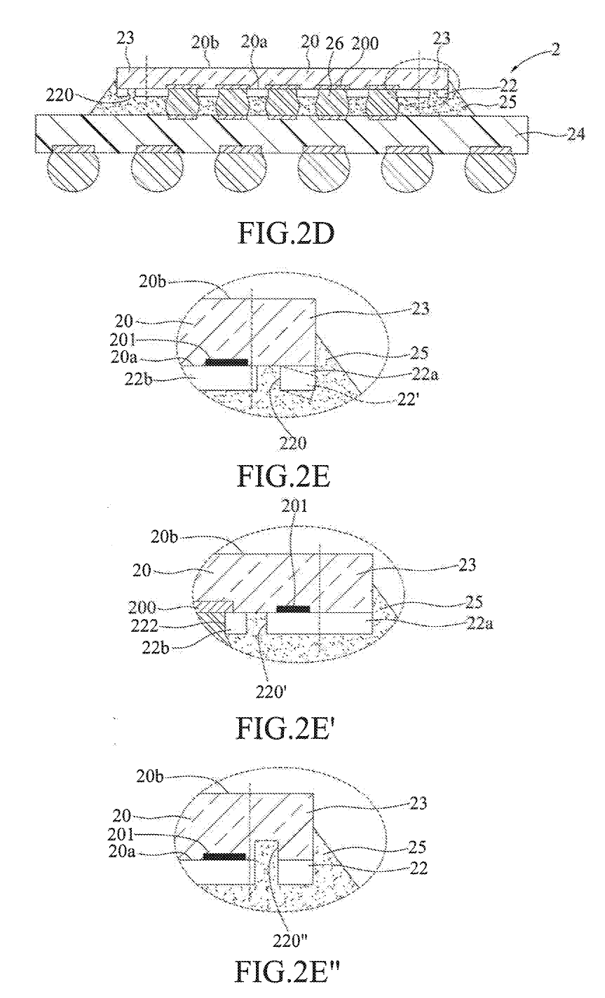

FIGS. 2A to 2C are schematic cross-sectional views showing a fabrication method of a semiconductor structure 2b according to the present invention.

FIG. 2B″ shows a bottom view of a semiconductor substrate 2a′ of the present invention.

FIGS. 2A to 2D show a fabrication method of a semiconductor package 2 according to the present invention,

Referring to FIG. 2A, a substrate body 2a is provided, which has a plurality of semiconductor elements 20 and a plurality of cutting portions 21 defined around peripheries of the semiconductor elements 20.

In the present embodiment, the substrate body 2a is a silicon wafer. Each of the semiconductor elements 20 has an active surface 20a with a plurality of electrode pads 200 and a non-active surface 20b opposite to the active surface 20a.

Further, a seal ring 201 is formed along edges of the active surface 20a of each of the semiconductor elements 20, as shown in FIG. 2B″.

Referring to FIG. 2B, an insulating layer 22 is formed on the substrate body 2a to cover the active surfaces 20a of the semiconductor elements 20 and the cutting portions 21. Further, a plurality of recessed portions 220 are formed in the insulating layer 22. In particular, there are at least two recessed portions 220 on each of the cutting portions 21. Further, the cutting portions 21 are partially exposed from the recessed portions 220.

In the present embodiment, the insulating layer 22 is a passivation layer, which can be made of such as polyimide (PI), benezocyclobutene (BCB) or polybenzoxazole (PBO). Further, the insulating layer 22 has a plurality of openings 222 for exposing the electrode pads 200 of the semiconductor elements 20.

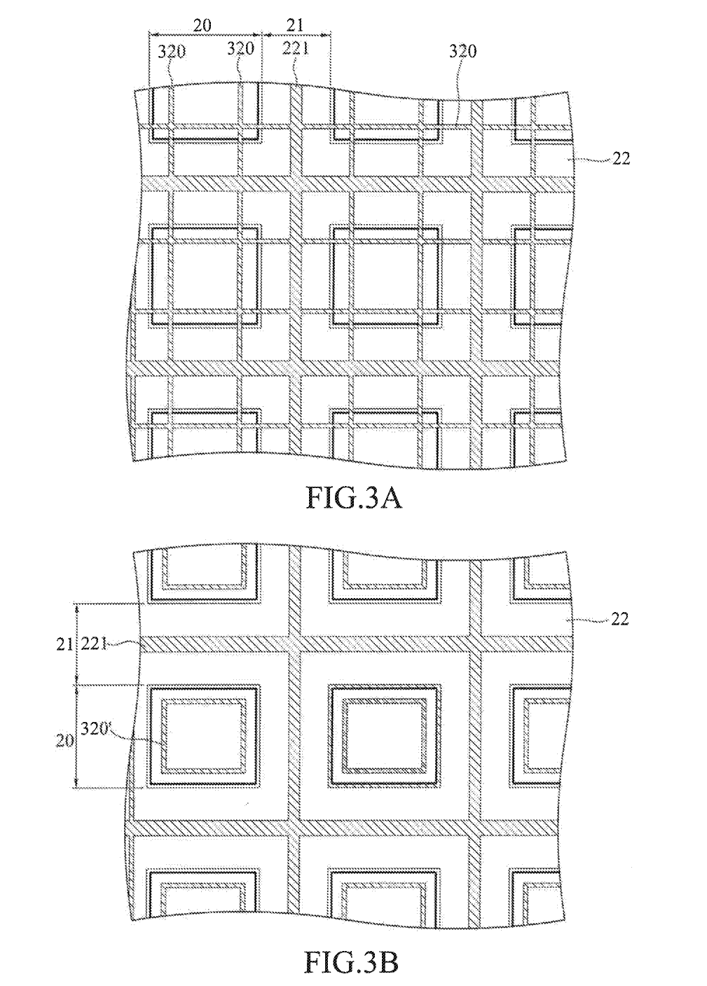

The recessed portions 220 can be formed by laser or exposure and development. The recessed portions 220 can have a linear shape (recessed portions 320 of FIG. 3A) or a ring shape (recessed portions 320′ of FIG. 3B).

In another embodiment, referring to FIG. 2B′, the recessed portions 220′ are formed on the active surfaces 20a of the semiconductor elements 20 for exposing portions of the active surfaces 20a.

Further, referring to FIG. 2B, a cutting process is performed along cutting paths S between the recessed portions 220. Alternatively, referring to FIG. 2B″, a cutting groove is formed between the recessed portions 220 on each of the cutting portions 21, and the width r of the cutting groove 221 is greater than the width w of the recessed portions 220, thus forming a semiconductor substrate 2a′. By cutting the semiconductor substrate along the cutting grooves 221, the semiconductor elements 20 are separated from each other, it should be noted that the insulating layer 22 on the active surfaces 20a of the semiconductor elements 20 are omitted in FIGS. 2B″, 3A and 3B to better show the seal rings 201. Further, the cutting portions 221 and the recessed portion 220 are shown as dashed areas in these drawings.

In other embodiments of the semiconductor substrate 2a′, if the recessed portions 220′ are formed on the active surfaces 20a of the semiconductor elements 20, a cutting groove 221 can be formed between the recessed portions 220′ of any two adjacent semiconductor elements 20.

Referring to FIG. 2C, continued from FIG. 2B, a singulation process is performed along the cutting paths S or the cutting grooves 221 to separate the semiconductor elements 20 from each other. Each of the semiconductor elements 20 has portions of the cutting portions 21 remaining at edges thereof to serve as a stopping portion 23 of the semiconductor elements 20. The recessed portions 220 are formed on the stopping portion 23.

In the present embodiment, the semiconductor element 20, the stopping portion 23 and the insulating layer 22 form a semiconductor structure 2b. The semiconductor element 20 has side surfaces 20c connecting the active surface 20a and the non-active surface 20b thereof; and the stopping portion 23 is defined on the side surfaces 20c of the semiconductor element 20.

The stopping portion 23 can be made of a semiconductor material and integrally formed with the semiconductor element 20.

Further, the stopping portion 23 is partially exposed from the recessed portions 220.

Referring to FIG. 2D, the semiconductor structure 2b is disposed on a packaging substrate 24 via the active surface 20a thereof. As such, the recessed portions 220 of the insulating layer 22 face the packaging substrate 24. Further, an encapsulant 25 is formed between the packaging substrate 24 and the insulating layer 22.

In the present embodiment, the electrode pads 200 of the semiconductor element 20 are electrically connected to the packaging substrate 24 through a plurality of conductive elements 26. The conductive elements 26 can be formed before or after the singulation process according to the practical need.

The encapsulant 25 can be made of an underfill or a molding compound.

Referring to FIG. 2E, the recessed portions 220 are formed at an outer periphery of the seal ring 20E For example, the recessed portions 220 are formed on the stopping portion 23. In other embodiments, the recessed portions 220′ can be formed at an inner side of the seal ring 201. For example, referring to FIG. 2E′, the recessed portions 220′ can be formed on the active surface 20a of the semiconductor element 20.

Referring to FIG. 2E″, the recessed portions 220″ extend into the stopping portion 23. In particular, the insulating layer 22 is laser ablated to form the recessed portions 220″ that extend into the stopping portion 23 and have a rough surface, thereby strengthening the bonding between the encapsulant 25 and the stopping portion 23.

Therefore, by forming the recessed portions 220, 220′ that separate the portion of the insulating layer 22 on the active surface 20a of the semiconductor element 20 and the portion of the insulating layer 22 on the stopping portion 23, the present invention allows the encapsulant 25 to cover more side surfaces of the insulating layer 22b. Therefore, during a reliability test, referring to FIG. 2E, even if delamination occurs between the insulating layer 22′ and the stopping portion 23 due to delamination of the encapsulant 25 from the semiconductor structure 2b, the recessed portions 220, 220′ can prevent the delamination from extending to the active surface 20a of the semiconductor element 20.

The semiconductor substrate 2a′ of the present invention has a substrate body 2a having a plurality of semiconductor elements 20 and an insulating layer 22 formed on the substrate body 2a.

Each of the semiconductor elements 20 has an active surface 20a and a non-active surface 20b opposite to the active surface 20a. A plurality of cutting portions 21 are defined around peripheries of the semiconductor elements 20.

The semiconductor elements 20 and the cutting portions 21 are covered by the insulating layer 22 and a plurality of recessed portions 220 are formed in the insulating layer 22.

In an embodiment, the insulating layer 22 further has a plurality of cutting grooves 221 corresponding to the cutting portions 21, respectively. The cutting grooves 221 have a width r greater than the width w of the recessed portions 220. Each of the cutting portions 21 can have two recessed portions 220 and the cutting groove 221 corresponding to the cutting portion 21 is formed between the two recessed portions 220. Alternatively, the recessed portions 220′, 320, 320′ are formed on the active surfaces 20a of the semiconductor elements 20 and each of the cutting grooves 221 is formed between the recessed portions 220′ of any two adjacent semiconductor elements 20.

The semiconductor structure 2b of the present invention has: a semiconductor element 20, a stopping portion 23 and an insulating layer 22.

Further, the semiconductor package 2 has: a semiconductor structure 2b, a packaging substrate 24 and an encapsulant 25.

The semiconductor element 20 has an active surface 20a with a plurality of electrode pads 200 and a non-active surface 20b opposite to the active surface 20a. The semiconductor element 20 is disposed on the packaging substrate 24 via the active surface 20a thereof. The electrode pads 200 are electrically connected to the packaging substrate 24 through a plurality of conductive elements 26.

The stopping portion 23 is formed at edges of the semiconductor element 20. The stopping portion 23 can be made of a semiconductor material and integrally formed with the semiconductor element 20.

The insulating layer 22 is formed on the active surface 20a of the semiconductor element 20 and the stopping portion 23 and exposing the electrode pads 200 of the semiconductor clement 20. The insulating layer 22 has at least a recessed portion 220, 220′, and the recessed portion 220, 220′ faces the packaging substrate 24.

The encapsulant 25 is formed between the packaging substrate 24 and the active surface 20a (or the insulating layer 22).

In an embodiment, the recessed portion 220, 220″ is formed on the stopping portion 23. Further, the stopping portion 23 is partially exposed from the recessed portion 220 or the recessed portion 220″ extends into the stopping portion 23.

In an embodiment, the recessed portion 22.0′, 320, 320′ is formed on the active surface 20a. Further, the active surface 20a is partially exposed from the recessed portion 220′.

In an embodiment, the recessed portion 320, 320′ has a linear shape or a ring shape.

Therefore, the recessed portion of the present invention causes the insulating layer to have a discontinuous structure such that during a reliability test, delamination of the insulating layer can be stopped by the recessed portion so as not to extend to the active surface of the semiconductor element, thereby increasing the product yield.

The above-described descriptions of the detailed embodiments are only to illustrate the preferred implementation according to the present invention, and it is not to limit the scope of the present invention. Accordingly, all modifications and variations completed by those with ordinary skill in the art should fall within the scope of present invention defined by the appended claims.

What is claimed is:

1. A semiconductor substrate, comprising:
a substrate body having a plurality of semiconductor elements and a plurality of cutting portions, wherein each of the semiconductor elements has opposite active and non-active surfaces, and the cutting portions are defined around peripheries of the semiconductor elements; and
an insulating layer formed on the substrate body for covering the semiconductor elements and the cutting portions, wherein the insulating layer has a plurality of recessed portions.

2. The substrate of claim 1, wherein the insulating layer further has a plurality of cutting grooves corresponding to the cutting portions, respectively.

3. The substrate of claim 2, wherein the cutting moves have a width greater than that of the recessed portions.

4. The substrate of claim 2, wherein each of the cutting portions has two of the recessed portions formed thereon and the cutting groove corresponding to the cutting portion is formed between the two recessed portions.

5. The substrate of claim 1, wherein the recessed portions have a linear shape or a ring shape.

6. The substrate of claim 1, wherein the recessed portions are formed on the active surfaces of the semiconductor elements.

7. The substrate of claim 6, wherein the insulating layer further has a plurality of cutting grooves corresponding to the cutting portions, respectively, and each of the cutting grooves is formed between the recessed portions of two adjacent ones of the semiconductor elements.

8. The substrate of claim 6, wherein the active surfaces of the semiconductor elements are partially exposed from the recessed portions.

9. The substrate of claim 1, wherein the recessed portions are formed on the cutting portions.

10. The substrate of claim 9, wherein the cutting portions are partially exposed from the recessed portions.

11. The substrate of claim 9, wherein the recessed portions extend into the cutting portions.

12. A semiconductor structure, comprising:
a semiconductor element having an active surface with a plurality of electrode pads and a non-active surface opposite to the active surface;
a stopping portion formed at edges of the semiconductor element; and
an insulating layer formed on the active surface of the semiconductor element and the stopping portion and exposing the electrode pads of the semiconductor element, wherein the insulating layer has at least a recessed portion.

13. The structure of claim 12, wherein the stopping portion and the semiconductor element are integrally formed.

14. The structure of claim 12, wherein the stopping portion is made of a semiconductor material.

15. The structure of claim 12, wherein the recessed portion has a linear shape or a ring shape.

16. The structure of claim 12, wherein the recessed portion is formed on the active surface of the semiconductor element.

17. The structure of claim 16, wherein the active surface of the semiconductor element is partially exposed from the recessed portion.

18. The structure of claim 12, wherein the recessed portion is formed on the stopping portion.

19. The structure of claim 18, wherein the stopping portion is partially exposed from the recessed portion.

20. The structure of claim 18, wherein the recessed portion extends into the stopping portion.

21. A semiconductor package, comprising:
a packaging substrate;
a semiconductor element having an active surface with a plurality of electrode pads and a non-active surface opposite to the active surface, wherein the semiconductor element is disposed on the packaging substrate via the active surface thereof;
a stopping portion formed at edges of the semiconductor element;
an insulating layer formed on the active surface of the semiconductor element and the stopping portion and exposing the electrode pads of the semiconductor element, wherein the insulating layer has at least a recessed portion; and
an encapsulant formed between the packaging substrate and the insulating layer.

22. The package of claim 21, wherein the electrode pads of the semiconductor element are electrically connected to the packaging substrate through a plurality of conductive elements.

23. The package of claim 21, wherein the stopping portion and the semiconductor element are integrally formed.

24. The package of claim 21, wherein the stopping portion is made of a semiconductor material.

25. The package of claim 21, wherein the recessed portion faces the packaging substrate.

26. The package of claim 21, wherein the recessed portion has a linear shape or a ring shape.

27. The package of claim 21, wherein the recessed portion is formed on the active surface of the semiconductor element.

28. The package of claim 27, wherein the active surface of the semiconductor element is partially exposed from the recessed portion.

29. The package of claim 21, wherein the recessed portion is formed on the stopping portion.

30. The package of claim 29, wherein the stopping portion is partially exposed from the recessed portion,

31. The package of claim 29, wherein the recessed portion extends into the stopping portion.

32. A fabrication method of a semiconductor substrate, comprising the steps of:
providing a substrate body having a plurality of semiconductor elements and a plurality of cutting portions, wherein each of the semiconductor elements has opposite active and non-active surfaces, and the cutting portions are defined around peripheries of the semiconductor elements; and
forming an insulating layer on the substrate body for covering the semiconductor elements and the cutting portions; and
forming a plurality of recessed portions in the insulating layer.

33. The method of claim 32, further comprising forming in the insulating layer a plurality of cutting grooves corresponding to the cutting portions, respectively.

34. The method of claim 33, wherein the cutting grooves have a width greater than that of the recessed portions.

35. The method of claim 33, wherein each of the cutting portions has two of the recessed portions formed thereon and the cutting groove corresponding to the cutting portion is formed between the two recessed portions.

36. The method of claim 32, wherein the recessed portions have a linear shape or a ring shape.

37. The method of claim 32, wherein the recessed portions are formed on the active surfaces of the semiconductor elements.

38. The method of claim 37, wherein the insulating layer further has a plurality of cutting grooves corresponding to the cutting portions, respectively, and each of the cutting grooves is formed between the recessed portions of two adjacent ones of the semiconductor elements.

39. The method of claim 37, wherein the active surfaces of the semiconductor elements are partially exposed from the recessed portions.

40. The method of claim 32, wherein the recessed portions are formed on the cutting portions.

41. The method of claim 40, wherein the cutting portions are partially exposed from the recessed portions.

42. The method of claim 40, wherein the recessed portions extend into the cutting portions.

43. The method of claim 32, wherein the recessed portions are formed by laser.

44. The method of claim 32, wherein the recessed portions are formed by exposure and development.

45. A fabrication method of a semiconductor package, comprising the steps of
providing a semiconductor structure, wherein the semiconductor structure comprises a semiconductor element having an active surface with a plurality of electrode pads and a non-active surface opposite to the active surface, a stopping portion formed at edges of the semiconductor element and an insulating layer formed on the active surface of the semiconductor element and the stopping portion and exposing the electrode pads of the semiconductor element, the insulating layer having at least a recessed portion;
disposing the semiconductor structure on a packaging substrate via the active surface thereof; and
forming an encapsulant between the packaging substrate and the insulating layer.

46. The method of claim 45, wherein forming the semiconductor structure comprises the steps of;
providing a substrate body having a plurality of semiconductor elements and a plurality of cutting portions, wherein the cutting portions are defined around peripheries of the semiconductor elements;
forming an insulating layer on the substrate body for covering the semiconductor elements and the cutting portions;
forming a plurality of recessed portions in the insulating layer;
cutting along the cutting portions to singulate the semiconductor elements, wherein portions of the cutting portions remain at edges of the semiconductor elements and serve as stopping portions of the semiconductor elements.

47. The method of claim 45, wherein the stopping portion and the semiconductor element are integrally formed.

48. The method of claim 45, wherein the stopping portion is made of a semiconductor material.

49. The method of claim 45, wherein the recessed portion faces the packaging substrate.

50. The method of claim 45, wherein the recessed portion has a linear shape or a ring shape.

51. The method of claim 45, wherein the recessed portion is formed on the active surface of the semiconductor element.

52. The method of claim 51, wherein the active surface of the semiconductor element is partially exposed from the recessed portion.

53. The method of claim 45, wherein the recessed portion is formed on the stopping portion.

54. The method of claim 53, wherein the stopping portion is partially exposed from the recessed portion.

55. The method of claim 53, wherein the recessed portion extends into the stopping portion.

56. The method of claim 45, wherein the recessed portion is formed by laser.

57. The method of claim 45, wherein the recessed portion is formed by exposure and development.

58. The method of claim 45, wherein the electrode pads of the semiconductor element are electrically connected to the packaging substrate through a plurality of conductive elements.
